(19) United States
(12) Patent Application Publication
(10) Pub. No.: US 2025/0366225 A1
(43) Pub. Date: Nov. 27, 2025

(54) RADIATION DETECTOR APPARATUS AND SYSTEM

(71) Applicant: TOWER SEMICONDUCTOR LTD., Migdal Haemek (IL)

(72) Inventors: Yakov Roizin, Afula (IL); Evgeny Pikhay, Haifa (IL); Inna Shehter, Kiryat Yam (IL); Avi Strum, Haifa (IL)

(73) Assignee: TOWER SEMICONDUCTOR LTD., Migdal Haemek (IL)

(21) Appl. No.: 18/674,884

(22) Filed: May 26, 2024

(51) Int. Cl. H01L 27/146

(52) U.S. Cl. CPC H10F 39/1892; H10F 39/8023; H10F 39/8037

(57) ABSTRACT

For example, a radiation detector may include a bonded die including a plurality of active pixel sensors configured to sense ionizing radiation. For example, the bonded die may include a detection die including a plurality of detection diodes. For example, an active pixel sensor of the plurality of active pixel sensors may include a detection diode of the plurality of detection diodes to generate an electric detection signal based on detected ionized radiation detected by the detection diode. For example, the bonded die may include an electronic-circuitry die bonded to the detection die. For example, a thickness of the electronic-circuitry die may be less than 4 percent of a thickness of the detection die. For example, the electronic-circuitry die may include a plurality of transistors. For example, the active pixel sensor may include one or more transistors of the plurality of transistors to amplify the electronic detection signal.

### BACKGROUND

Radiation detectors may be implemented to detect ionizing radiation.

In one example, radiation detectors may be implemented, for example, as part of medical devices, e.g., as part of a Computed Tomography (CT) scan device.

In another example, radiation detectors may be implemented, for example, as part of nuclear devices, e.g., as part of a particle detector of a particle accelerator.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic block diagram illustration of a radiation detector, in accordance with some demonstrative aspects.

FIG. 2 is a schematic illustration of a radiation detector including a plurality of stacked bonded dies, in accordance with some demonstrative aspects.

FIG. 3 is a schematic illustration of a radiation detector including a plurality of stacked bonded dies, in accordance with some demonstrative aspects.

FIG. 4 is a schematic illustration of a diffusion-bonded die, in accordance with some demonstrative aspects.

FIG. 5 is a schematic illustration of a hybrid-bonded die, in accordance with some demonstrative aspects.

FIG. 6 is a schematic illustration of an electronic device, in accordance with some demonstrative aspects.

### DETAILED DESCRIPTION

In the following detailed description, numerous specific details are set forth in order to provide a thorough understanding of some aspects. However, it will be understood by persons of ordinary skill in the art that some aspects may be practiced without these specific details. In other instances, well-known methods, procedures, components, units and/or circuits have not been described in detail so as not to obscure the discussion.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality”, as used herein, include, for example, “multiple” or “two or more”. For example, “a plurality of items” includes two or more items.

References to “one aspect”, “an aspect”, “demonstrative aspect”, “various aspects” etc., indicate that the aspect(s) so described may include a particular feature, structure, or characteristic, but not every aspect necessarily includes the particular feature, structure, or characteristic. Further, repeated use of the phrase “in one aspect” does not necessarily refer to the same aspect, although it may.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

The phrases “at least one” and “one or more” may be understood to include a numerical quantity greater than or equal to one, e.g., one, two, three, four, [ . . . ], etc. The phrase “at least one of” with regard to a group of elements may be used herein to mean at least one element from the group consisting of the elements. For example, the phrase “at least one of” with regard to a group of elements may be used herein to mean one of the listed elements, a plurality of one of the listed elements, a plurality of individual listed elements, or a plurality of a multiple of individual listed elements.

The terms “substrate” and/or “wafer”, as used herein, may relate to a thin slice of semiconductor material, for example, a silicon crystal, which may be used in fabrication of integrated circuits and/or any other microelectronic devices. For example, the wafer may serve as the substrate for the microelectronic devices, which may be built in and over the wafer.

The term “Integrated Circuit” (IC), as used herein, may relate to a set of one or more electronic circuits on a semiconductor material. For example, an electronic circuit may include electronic components and their interconnectors.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and/or may represent any information as understood in the art.

The terms “processor” or “controller” may be understood to include any kind of technological entity that allows handling of any suitable type of data and/or information. The data and/or information may be handled according to one or more specific functions executed by the processor or controller. Further, a processor or a controller may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), and the like, or any combination thereof. Any other kind of implementation of the respective functions, which will be described below in further detail, may also be understood as a processor, controller, or logic circuit. It is understood that any two (or more) processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The term “memory” is understood as a computer-readable medium (e.g., a non-transitory computer-readable medium) in which data or information can be stored for retrieval. References to “memory” may thus be understood as referring to volatile or non-volatile memory, including random access memory (RAM), read-only memory (ROM), flash memory, solid-state storage, magnetic tape, hard disk drive, optical drive, among others, or any combination thereof. Registers, shift registers, processor registers, data buffers, among others, are also embraced herein by the term memory. The term “software” may be used to refer to any type of executable instruction and/or logic, including firmware.

The term “circuitry”, as used herein, may refer to, be part of, or include, an Application Specific Integrated Circuit (ASIC), an integrated circuit, an electronic circuit, a processor (shared, dedicated, or group), and/or memory (shared, dedicated, or group), that execute one or more software or firmware programs, a combinational logic circuit, and/or other suitable hardware components that provide the described functionality. In some aspects, some functions associated with the circuitry may be implemented by one or more software or firmware modules. In some aspects, circuitry may include logic, at least partially operable in hardware.

The term “logic” may refer, for example, to computing logic embedded in circuitry of a computing apparatus and/or computing logic stored in a memory of a computing apparatus. For example, the logic may be accessible by a processor of the computing apparatus to execute the computing logic to perform computing functions and/or operations. In one example, logic may be embedded in various types of memory and/or firmware, e.g., silicon blocks of various chips and/or processors. Logic may be included in, and/or implemented as part of, various circuitry, e.g., radio circuitry, receiver circuitry, control circuitry, transmitter circuitry, transceiver circuitry, processor circuitry, and/or the like. In one example, logic may be embedded in volatile memory and/or non-volatile memory, including random access memory, read only memory, programmable memory, magnetic memory, flash memory, persistent memory, and/or the like. Logic may be executed by one or more processors using memory, e.g., registers, buffers, stacks, and the like, coupled to the one or more processors, e.g., as necessary to execute the logic.

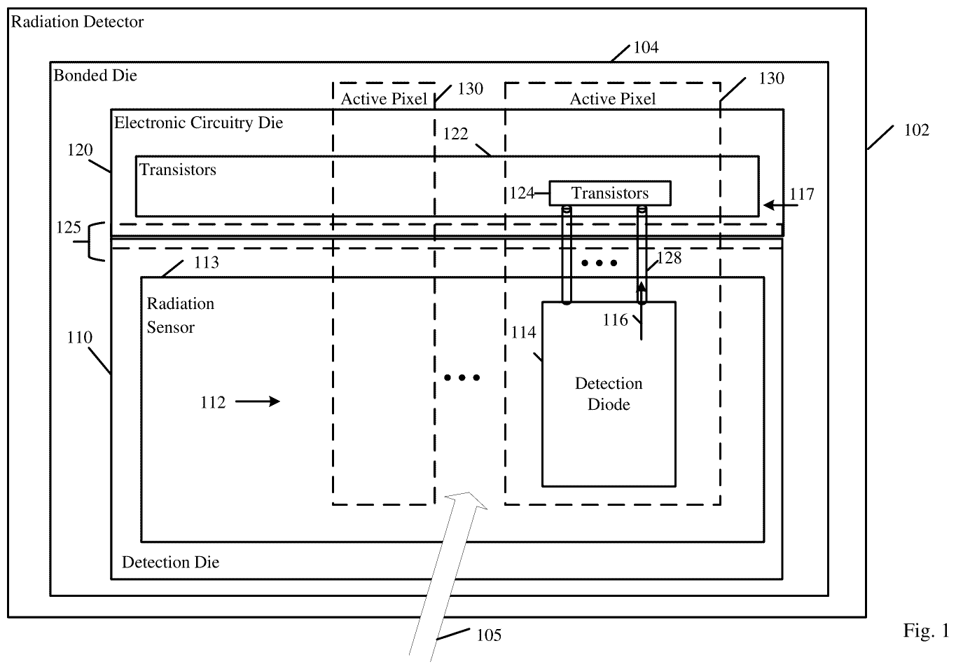

Reference is made to FIG. 1, which schematically illustrates a block diagram of a radiation detector 102, in accordance with some demonstrative aspects.

In some demonstrative aspects, radiation detector 102 may be configured to detect ionizing radiation 105, e.g., as described below.

In some demonstrative aspects, ionizing radiation 105 may include gamma radiation. For example, ionizing radiation 105 may include X-rays.

In one example, radiation detector 102 may be implemented, for example, as part of a medical device, e.g., as part of a Computed Tomography (CT) scan device.

In some demonstrative aspects, ionizing radiation 105 may include energetic particles, e.g., high energy particles.

In one example, radiation detector 102 may be implemented, for example, as part of nuclear devices, e.g., as part of a particle detector of a particle accelerator.

In other aspects, ionizing radiation 105 may include any other suitable additional or alternative type of radiation.

In other aspects, radiation detector 102 may be implemented as part of any other suitable additional or alternative type of device.

In some demonstrative aspects, radiation detector 102 may be configured to convert the ionizing radiation 105 into an electronic signal, e.g., as described below.

In some demonstrative aspects, radiation detector 102 may include a radiation sensor, which may be configured to detect the ionizing radiation 105, and to generate a plurality of electric detection signals based on detected ionized radiation, e.g., of the ionizing radiation 105, e.g., as described below.

In some demonstrative aspects, the radiation sensor 113 may include a plurality of detection diodes 112, which may be configured to detect the ionizing radiation 105, and to generate the plurality of electric detection signals based on the detected ionized radiation, e.g., of the ionizing radiation 105, e.g., as described below.

In some demonstrative aspects, radiation detector 102 may include electronic circuitry 117, which may be configured to amplify the plurality of electric detection signals from the plurality of detection diodes 112, e.g., as described below.

In some demonstrative aspects, electronic circuitry 117 may include a plurality of transistors 122, which may be configured to amplify the plurality of electric detection signals from the plurality of detection diodes 112, e.g., as described below.

In one example, the plurality of detection diodes 112 may be configured to collect, for example, by diffusion and/or an electric field, electron-hole pairs, which may be created by the ionizing radiation 105.

In some demonstrative aspects, radiation detector 102 may include a plurality of Active Pixel Sensors (APS) 130, which may be configured to sense the ionizing radiation 105, e.g., as described below.

In some demonstrative aspects, radiation detector 102 may include a Monolithic Active Pixel Sensor (MAPS), e.g., as described below.

In some demonstrative aspects, radiation detector 102 may include a three dimensional (3D) MAPS radiation detector, e.g., as described below.

In one example, the 3D MAPS radiation detector may include a 3D edge-on ionizing radiation detector.

In some demonstrative aspects, the 3D MAPS may include a plurality of stacked sets of active pixel sensors 130, e.g., as described below.

In some demonstrative aspects, in some use cases, scenarios, and/or implementations, there may be one or more technical inefficiencies, disadvantages and/or problems in implementations of a radiation sensor on one or more thin silicon layers.

For example, a MAPS device may include silicon substrates with relatively thin epitaxial high resistance layers, in which electron-hole pairs may be created, e.g., by ionizing radiation, and collected, e.g., by an electric field and diffusion.

For example, the epitaxial high resistance layers may be configured to have a width in the range between 10-15 micrometer (um), or any other suitable width.

In one example, the thin epitaxial high resistance layers may not be suitable to support high detection volumes, may have a slow charge collection, and/or may have a degraded radiation hardness.

In some demonstrative aspects, the radiation sensor 113 may be implemented based on fully depleted silicon diodes on a Float Zone (FZ) silicon, for example, to provide a technical solution to support high detection volumes, relatively fast charge collection, and/or improved radiation hardness.

In some demonstrative aspects, the plurality of detection diodes 112 may include fully depleted silicon diodes on FZ silicon, e.g., as described below.

In some demonstrative aspects, in some use cases, scenarios, and/or implementations, there may be one or more technical inefficiencies, disadvantages and/or problems in integration of a radiation sensor, which is based on FZ silicon, together with signal processing circuitry, e.g., on a same wafer.

In one example, in some use cases it may be impractical to integrate fully depleted silicon diodes, e.g., of an all-depleted 650 um thick silicon sensor, together with signal processing circuitry, for example, in one semiconductor process flow. For example, standard Complementary Metal-Oxide-Semiconductor (MOS) (CMOS) fabrication of the signal processing circuitry may not allow maintaining a high resistance of an FZ wafer, which may be required to fabricate the fully depleted detection diodes of the radiation sensor.

In another example, integration of fully depleted silicon diodes together with the signal processing circuitry in one semiconductor process flow may result in a detector having thick signal processing circuitry.

In some demonstrative aspects, in some use cases, scenarios, and/or implementations, there may be one or more technical inefficiencies, disadvantages and/or problems in integration of a radiation sensor based on fully depleted silicon together with thick signal processing circuitry in one semiconductor process flow, e.g., as described below.

In one example, the thick signal processing circuitry may not support efficient implementation of a 3D MAPS. For example, a thick layer with CMOS devices, which is attached to a fully depleted FZ silicon radiation sensor, may not support stacking of a plurality of dices, e.g., where each die includes a 650 um thick. For example, stacking the plurality of dices may result in thick layers with CMOS devices between stacked dices, which may result in a large number of dead sensing zones.

In another example, the thick signal processing circuitry may have a high number of displacement damages. For example, these displacement damages may include trap generation by high energy and/or a high dose of photons or particles. For example, the number of displacement damages may be a critical factor for higher energy X-ray or Gamma radiation detectors and/or high energy particle radiation detectors. For example, a number of defects influencing transistor performance may be larger in a thick silicon, e.g., compared with micrometer thick CMOS layers.

In another example, the thick signal processing circuitry may suffer from a degraded radiation immunity. For example, thick signal processing circuitry may suffer from Single-Event Upset (SEU) phenomena, e.g., like latch-ups. For example, the thick signal processing circuitry may suffer from low tolerance to soft errors, which may be a critical factor for sensors working in a single electron registration mode, e.g., for counting pulses.

In some demonstrative aspects, radiation detector 102 may be configured to provide a technical solution to support a radiation sensor including FZ silicon and thin signal processing circuitry, e.g., as described below.

In some demonstrative aspects, radiation detector 102 may include a radiation sensor 113, which may be based on fully depleted silicon, e.g., as described below.

In some demonstrative aspects, the radiation sensor 113, which may be based on fully depleted silicon, may be integrated with thin CMOS registration circuitry, for example, by direct bonding of two wafers, e.g., as described below.

In some demonstrative aspects, radiation detector 102 may be configured to provide a technical solution to support registration of gamma radiation and/or energetic particles, e.g., as described below.

In some demonstrative aspects, radiation detector 102 may be configured to implement P-type-Intrinsic-region-N-type (PIN) diodes, which may operate at a full depletion regime. For example, substantially an entire volume of the radiation sensor 113 may be depleted of electrons and holes, e.g., as described below.

In some demonstrative aspects, radiation detector 102 may implement and/or may integrate a thick fully depleted radiation sensor 113, e.g., including the plurality of detection diodes 112, and relatively thin signal processing circuitry 117, for example, including the plurality of transistors 122, e.g., as described below.

In some demonstrative aspects, the thick fully depleted radiation sensor 113 may be implemented, for example, on a first wafer, e.g., including a first semiconductor material.

In some demonstrative aspects, the thick fully depleted radiation sensor 113 may be implemented on a high resistivity FZ silicon wafer. For example, the high resistivity FZ silicon wafer may be fully depleted. For example, substantially an entire thickness of the FZ silicon wafer, e.g., a thickness of about 650 um, may be fully depleted. For example, substantially an entire volume of the radiation sensor 113 may be depleted of electrons and holes.

In some demonstrative aspects, the thin signal processing circuitry 117 may be implemented, for example, on a second wafer, e.g., including a second semiconductor material.

In some demonstrative aspects, the thin signal processing circuitry 117 may be implemented on a CMOS wafer, e.g., a Silicon On Insulator (SOI) wafer or any other CMOS wafer, for example, using one or more suitable CMOS processes, e.g., using very thin layers of silicon with CMOS circuits.

In some demonstrative aspects, the first wafer and the second wafer may be bonded to form a bonded wafer, e.g., as described below.

In some demonstrative aspects, the thin signal processing circuitry 117 may be formed by etching the second wafer of the bonded wafer, e.g., the SOI CMOS wafer, for example, to reduce a thickness of the signal processing circuitry on the CMOS wafer. For example, a Buried Oxide (BOX) layer of the SOI may act as an etch stop during the thinning of the CMOS wafer.

In some demonstrative aspects, radiation detector 102 may include a bonded die 104, e.g., as described below.

In some demonstrative aspects, the bonded die 104 may include a first die and a second die, e.g., as described below.

In some demonstrative aspects, the bonded die 104 maybe manufactured using a bonded wafer including a first wafer bonded to second wafer, e.g., as described below. For example, the first wafer may include the FZ silicon wafer, and the second wafer may include the SOI wafer, e.g., as described above.

In some demonstrative aspects, the bonded die 104 may include the plurality of active pixel sensors 130, which may be configured to sense the ionizing radiation 105, e.g., as described below.

In some demonstrative aspects, the bonded die 104 may include a detection die 110, e.g., as described below.

In some demonstrative aspects, the detection die 110 may include a plurality of detection diodes 112, e.g., as described below.

In some demonstrative aspects, an active pixel sensor 130 of the plurality of active pixel sensors 130 may include a detection diode 114 of the plurality of detection diodes 112, for example, to generate an electric detection signal 116, for example, based on detected ionized radiation, which may be detected by the detection diode 114, e.g., as described below.

In some demonstrative aspects, the detection diode 114 may include a P-type-Intrinsic-region-N-type (PIN) diode.

In other aspects, the detection diode 114 may include any other type of diode.

In some demonstrative aspects, the bonded die 104 may include an electronic-circuitry die 120, e.g., as described below.

In some demonstrative aspects, the electronic-circuitry die 120 may be bonded to the detection die 110, e.g., as described below.

In some demonstrative aspects, the electronic-circuitry die 120 may include the plurality of transistors 122, e.g., as described below.

In some demonstrative aspects, the active pixel sensor 130 may include one or more transistors 124 of the plurality of transistors 122, which may be configured to amplify the electronic detection signal 116, e.g., as described below.

In some demonstrative aspects, a thickness of the electronic-circuitry die 120 may be less than 4 percent of a thickness of the detection die 110, e.g., as described below.

In some demonstrative aspects, the thickness of the electronic-circuitry die 120 may be no more than 3.5 percent of the thickness of the detection die 110, e.g., as described below.

In some demonstrative aspects, the thickness of the electronic-circuitry die 120 may be no more than 3 percent of the thickness of the detection die 110, e.g., as described below.

In some demonstrative aspects, the thickness of the electronic-circuitry die 120 may be no more than 2.5 percent of the thickness of the detection die 110, e.g., as described below.

In some demonstrative aspects, the thickness of the electronic-circuitry die 120 may be no more than 2 percent of the thickness of the detection die 110, e.g., as described below.

In other aspects, the thickness of the electronic-circuitry die 120 and the thickness of the detection die 110 may be implemented according to any other suitable ratio.

In some demonstrative aspects, the thickness of the detection die 110 may be at least 600 um, e.g., as described below.

In some demonstrative aspects, the thickness of the detection die 110 may be at least 640 um, e.g., as described below.

In some demonstrative aspects, the thickness of the detection die 110 may be at least 650 um, e.g., as described below.

In other aspects, the detection die 110 may have any other thickness.

In some demonstrative aspects, the thickness of the electronic-circuitry die 120 may be no more than 15 um, e.g., as described below.

In some demonstrative aspects, the thickness of the electronic-circuitry die 120 may be no more than 10 um, e.g., as described below.

In some demonstrative aspects, the thickness of the electronic-circuitry die 120 may be no more than 5 um, e.g., as described below.

In other aspects, the electronic-circuitry die 120 may have any other thickness.

In some demonstrative aspects, the detection die 110 may include FZ silicon, e.g., as described below.

In some demonstrative aspects, the detection die 110 may include high-resistance FZ silicon, e.g., as described below.

In some demonstrative aspects, the detection die 110 may include fully-depleted silicon, e.g., as described below.

In some demonstrative aspects, the detection die 110 may include a Czochralski silicon die, e.g., as described below.

In some demonstrative aspects, the detection die 110 may include a high-resistance Czochralski silicon die, e.g., as described below.

In other aspects, the detection die 110 may include any other type of high-resistance silicon and/or fully depleted silicon.

In some demonstrative aspects, the detection die 110 may include an N-type-conductivity detection die, e.g., as described below.

In some demonstrative aspects, the N-type-conductivity detection die may include one or more heavily doped P-type (P+) regions, which may be connected to one or more metal pads, e.g., as described below.

In some demonstrative aspects, the N-type-conductivity detection die may include a heavily doped N-type (N+) layer on an external side of the detection die 110, e.g., as described below.

In one example, the N-type-conductivity detection die may include P+ regions connected to Aluminum (Al) pads, which may be covered by passivation dielectric layers. For example, the passivation dielectric layers may include silicon oxide silicon nitride and/or oxynitride. For example, the N-type-conductivity detection die may include N+ doping and Al metallization at a back side of the N-type-conductivity detection die.

In some demonstrative aspects, the detection die 110 may include a P-type-conductivity detection die, e.g., as described below.

In some demonstrative aspects, the P-type-conductivity detection die may include one or more heavily doped N-type regions, which may be connected to one or more metal pads, e.g., as described below.

In some demonstrative aspects, the P-type-conductivity detection die may include a heavily doped P-type layer on the external side of the detection die 110, e.g., as described below.

In one example, the P-type-conductivity detection die may include N+ regions connected to Al pads, which may be covered by passivation dielectric layers. For example, the passivation dielectric layers may include silicon oxide silicon nitride and/or oxynitride. For example, the P-type-conductivity detection die may include P+ doping and Al metallization at the back side of the P-type-conductivity detection die.

In some demonstrative aspects, the electronic-circuitry die 120 may include a CMOS die, e.g., as described below.

In some demonstrative aspects, the CMOS die may include an SOI, e.g., as described below.

In some demonstrative aspects, the CMOS die may include Gallium-Nitride (GaN), e.g., as described below.

In one example, the electronic-circuitry die 120 may be implemented to include a GaN die, for example, to provide a technical solution to support increased radiation hardness of the electronic-circuitry die 120.

In some demonstrative aspects, the CMOS die may include Silicon-Germanium (SiGe).

In one example, the electronic-circuitry die 120 may be implemented to include an SiGe die, for example, to provide a technical solution to support a higher speed of the electronic-circuitry die 120.

In some demonstrative aspects, the CMOS die may include Gallium-Arsenide (GaAs), e.g., as described below.

In some demonstrative aspects, the CMOS die may include any other type of material.

In some demonstrative aspects, the CMOS die may include a plurality of MOS transistors, e.g., as described below.

For example, the plurality of transistors 122 may include a plurality of MOS transistors.

In some demonstrative aspects, the plurality of MOS transistors may include a plurality of N-type MOS (NMOS) transistors, e.g., as described below.

For example, the plurality of transistors 122 may include a plurality of NMOS transistors.

In some demonstrative aspects, the plurality of MOS transistors may include a plurality of P-type MOS (PMOS) transistors, e.g., as described below.

For example, the plurality of transistors 122 may include a plurality of PMOS transistors.

In other aspects, the plurality of transistors 122 may include any other additional or alternative type of transistors.

In some demonstrative aspects, bonded die 104 may include a bonding layer 125, for example, to bond the electronic-circuitry die 120 and the detection die 110, e.g., as described below.

In some demonstrative aspects, the bonding layer 125 may include a plurality of vias 128 to connect the plurality of detection diodes 112 to the plurality of transistors 122, e.g., as described below.

In some demonstrative aspects, the bonding layer 125 may include a fusion bonding layer, e.g., as described below.

In some demonstrative aspects, the fusion bonding layer may be configured to fuse a dielectric layer of the electronic-circuitry die 120 with a dielectric layer of the detection die 110, e.g., as described below.

In some demonstrative aspects, the bonding layer 125 may include a hybrid bonding layer, e.g., as described below.

In some demonstrative aspects, the hybrid bonding layer may be configured to bond dielectric regions and metal vias of the electronic-circuitry die 120 with corresponding dielectric regions and metal vias of the detection die 110, e.g., as described below.

In some demonstrative aspects, the radiation detector 102 may include a MAPS, e.g., as described below.

In some demonstrative aspects, the radiation detector 102 may include a 3D MAPS, e.g., as described below.

In some demonstrative aspects, the radiation detector 102 may include a plurality of stacked bonded dies 104 to detect the ionizing radiation 105, e.g., as described below.

In some demonstrative aspects, the plurality of stacked bonded dies 104 may include a plurality of connection pads (not shown in FIG. 1), e.g., as described below.

In some demonstrative aspects, the plurality of connection pads may be arranged in a cascaded arrangement, e.g., as described below.

In other aspects, the plurality of connection pads may be arranged in any other suitable arrangement.

In some demonstrative aspects, the plurality of stacked bonded dies may include a plurality of spaces between the plurality of connection pads, e.g., as described below.

In some demonstrative aspects, a connection pad of a stacked bonded die including the bonded die 104 may be configured, for example, to provide a plurality of amplified detection signals from the plurality of active pixels 130, e.g., as described below.

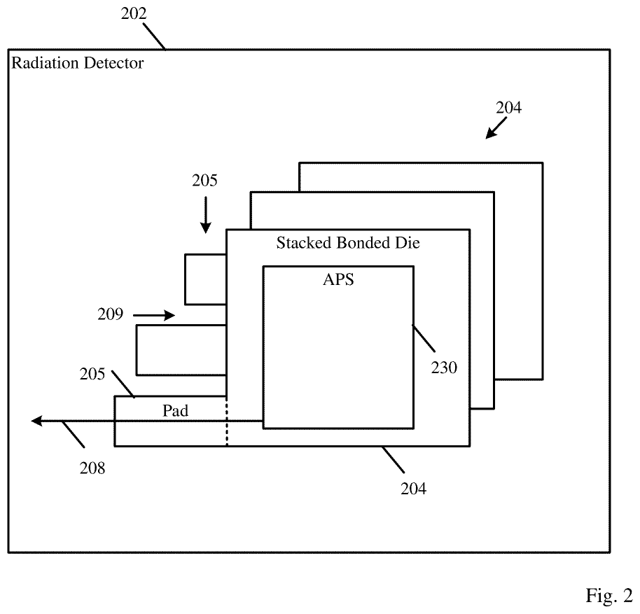

Reference is made to FIG. 2, which schematically illustrates a radiation detector 202 including a plurality of stacked bonded dies 204, in accordance with some demonstrative aspects. For example, radiation detector 102 (FIG. 1) may include one or more elements of radiation detector 202 and/or may perform one or more operations of radiation detector 202.

In some demonstrative aspects, as shown in FIG. 2, the plurality of stacked bonded dies 204 may include a plurality of connection pads 205. For example, the plurality of connection pads 205 may include 3D stacking pads.

In some demonstrative aspects, as shown in FIG. 2, the plurality of connection pads 205 may be arranged in a cascaded arrangement, for example, to support connection of the plurality of stacked bonded dies 204, e.g., to external circuitry and/or logic.

In some demonstrative aspects, as shown in FIG. 2, the plurality of stacked bonded dies 204 may include a plurality of spaces 209 between the plurality of connection pads 205, for example, to support connection of the plurality of stacked bonded dies 204, e.g., to the external circuitry and/or logic.

In one example, the plurality of connection pads 205 may be configured for connection to one or more decoders and one or more multiplexers, for example, to select active pixels from the plurality of stacked bonded dies 204.

In some demonstrative aspects, as shown in FIG. 2, a stacked bonded die 204, e.g., including the bonded die 104 (FIG. 1), may include a connection pad 205 and a plurality of active pixel sensors 230, e.g., the plurality of active pixel sensors 130 (FIG. 1).

In some demonstrative aspects, the connection pad 205 of the stacked bonded die 204 may be configured to provide a plurality of amplified detection signals 208 from the plurality of active pixels 230, e.g., to the external circuitry and/or logic.

Referring back to FIG. 1, in some demonstrative aspects, the radiation detector 102 may include a plurality of stacked bonded dies 104, which may include a connection interface on an external stacked bonded die (not shown in FIG. 1), e.g., as described below.

In some demonstrative aspects, the plurality of stacked bonded dies 104 may include a plurality of Through-Silicon Vias (TSVs) (not shown in FIG. 1), for example, to connect between the connection interface and transistors of the plurality of stacked bonded dies 104, e.g., as described below.

In some demonstrative aspects, the plurality of TSVs may include a plurality of alignment TSVs, which may be configured to align stacking of the plurality of stacked bonded dies. For example, the alignment TSVs may be utilized as “dummy” TSVs, which may be used as alignment marks for alignment of wafer stacking.

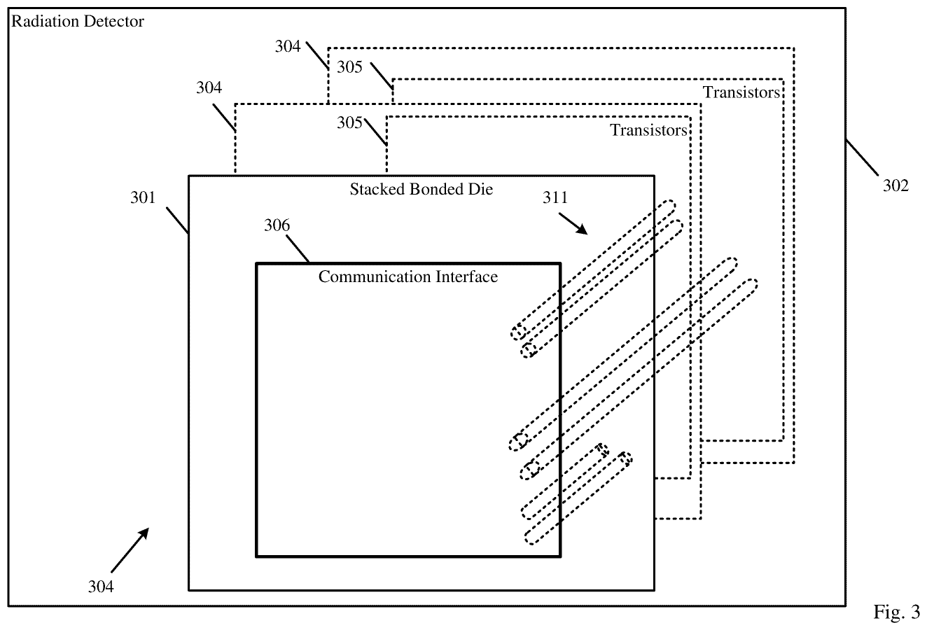

Reference is made to FIG. 3, which schematically illustrates a radiation detector 302 including a plurality of stacked bonded dies 304, in accordance with some demonstrative aspects. For example, radiation detector 102 (FIG. 1) may include one or more elements of radiation detector 302 and/or may perform one or more operations of radiation detector 302.

In some demonstrative aspects, as shown in FIG. 3, the plurality of stacked bonded dies 304 may include a connection interface 306, for example, on an external stacked bonded die 301.

In some demonstrative aspects, as shown in FIG. 3, the plurality of stacked bonded dies 304 may include a plurality of TSVs 311, for example, to connect between the connection interface 306 and transistors 305 of the plurality of stacked bonded dies 304.

In some demonstrative aspects, one or more TSVs of the plurality of TSVs 311 may include “dummy” TSVs, which may be used as alignment TSVs, for example, to align stacking of the plurality of stacked bonded dies 304.

Referring back to FIG. 1, in some demonstrative aspects, radiation detector 102 may be configured to provide a technical solution to support registration of gamma radiation and/or energetic particles, e.g., as described below.

In some demonstrative aspects, radiation detector 102 may be configured to provide a technical solution to support implementation of a 3D ionizing radiation detector, e.g., for detection of X-rays and/or energetic particles, for example, with improved resolution, e.g., spatial and/or energy resolution.

In some demonstrative aspects, radiation detector 102 may be configured to provide a technical solution to support increased detection volumes, faster charge collection, and/or enhanced radiation hardness, e.g., as described below.

In some demonstrative aspects, radiation detector 102 may be configured to provide a technical solution to support integration of PIN diode sensors and CMOS electronics in an active pixel sensor, e.g., as described below.

In some demonstrative aspects, radiation detector 102 may be configured to provide a technical solution to support implementation of radiation detectors with reduced cost and/or enhanced reliability, e.g., compared to common detectors of ionizing radiation.

In some demonstrative aspects, radiation detector 102 may be configured to provide a technical solution to support radiation detection in a wide range of technological fields.

In one example, radiation detector 102 may be configured to provide a technical solution to support X-ray detection for medical imaging systems, e.g., edge-on detectors for CT scanning.

In another example, radiation detector 102 may be configured to provide a technical solution to support nuclear physics devices, security devices and/or aerospace devices.

In some demonstrative aspects, bonded die 104 may be implemented, for example, to provide a technical solution to support a 3D integration, in which a plurality of bonded dies 104 may be stacked to form a 3D radiation sensor, e.g., a 3D MAPS and/or any other suitable type of 3D sensor.

In some demonstrative embodiments, bonded die 104 may include very thin layers with CMOS devices, e.g., electronic-circuitry die 120, which may be attached to a fully depleted FZ silicon radiation sensor, e.g., detection die 110.

For example, this implementation of bonded die 104 may provide a technical solution to support stacking of fully depleted FZ silicon radiation sensors, e.g., 650 um thick sensor dices, with very small spaces between them, e.g., including very thin layers with CMOS devices. For example, this ability to stack the fully depleted FZ silicon radiation sensors with very small spaces between them may provide a technical solution to exclude “dead sensing zones”.

In some demonstrative aspects, radiation detector 102 may be configured to provide a technical solution to support a reduced number of displacement damage defects. For example, displacement damages may have a reduced influence on device performance, e.g., due to the very thin layer of CMOS wafer, e.g., implementing electronic-circuitry die 120, influence of. For example, radiation detector 102 may be implemented with the reduced number of displacement damage defects, for example, to support high energy photon sensing applications, and/or particle sensing applications, for example, without any degradation.

In some demonstrative aspects, radiation detector 102 may be configured to provide a technical solution to support improved radiation immunity and/or improved radiation hardness. For example, the very thin layer with CMOS devices, e.g., electronic-circuitry die 120, may suppress SEU phenomena, e.g., latch-ups. Accordingly, radiation detector 102 may provide a high tolerance for soft errors. For example, the improved radiation immunity may be critical for sensors working in a single electron registration mode, e.g., counting pulses.

In some demonstrative aspects, bonded die 104 may be fabricated according to a two-wafer-bonding process, e.g., as described below.

In some demonstrative aspects, the detection die 110 may be fabricated on a first semiconductor material on a first wafer.

In some demonstrative aspects, the first wafer may include an FZ silicon wafer.

In some demonstrative aspects, the FZ silicon wafer may include a plurality of detection dies 110.

In some demonstrative aspects, electronic-circuitry die 120 may be fabricated on a second semiconductor material on a second wafer.

In some demonstrative aspects, the second wafer may include a CMOS wafer. For example, electronic-circuitry die 120 may be formed in a thin epitaxial (epi) layer, or on device layer, of an SOI wafer.

In some demonstrative aspects, the CMOS wafer may include a plurality of electronic-circuitry dies 120.

In some demonstrative aspects, the first wafer, e.g., the FZ wafer, and the second wafer, e.g., the CMOS wafer, may be fabricated separately.

In one example, the first wafer, e.g., the FZ wafer, and the second wafer, e.g., the CMOS wafer, may be fabricated using different manufacturing machines, manufacturing operations, manufacturing materials, manufacturing processes, and/or the like.

In another example, the first wafer, e.g., the FZ wafer, and the second wafer, e.g., the CMOS wafer, may be fabricated using one or more, e.g., some or all, of the same set of tools, the same set of manufacturing machines, and/or the same technological process.

In one example, the first wafer, e.g., the FZ wafer, and the second wafer, e.g., the CMOS wafer, may be fabricated substantially simultaneously.

In another example, the first wafer, e.g., the FZ wafer, and the second wafer, e.g., the CMOS wafer, may be fabricated sequentially.

In some demonstrative aspects, the first wafer, e.g., the FZ wafer, and the second wafer, e.g., the CMOS wafer, may be bonded into a bonded wafer.

In some demonstrative aspects, the bonded wafer may include a plurality of bonded dies 104.

In some demonstrative aspects, the bonded wafer may include the first wafer, e.g., the FZ wafer, and the second wafer, e.g., the CMOS wafer.

In some demonstrative aspects, the first wafer, e.g., the FZ wafer, and the second wafer, e.g., the CMOS wafer, may be bonded, for example, while maintaining a high resistivity of the FZ wafer.

In one example, the first wafer, e.g., the FZ wafer, and the second wafer, e.g., the CMOS wafer, may be bonded, for example, while utilizing one or more low temperature processes, e.g., temperatures below 350 degrees Celsius, for example, to maintain the high resistivity of the FZ wafer.

In some demonstrative aspects, the first wafer, e.g., the FZ wafer, and the second wafer, e.g., the CMOS wafer, may be bonded, for example, using one or more patterns, aligners, steppers, and/or the like, for example, to align the first wafer to the second wafer.

In some demonstrative aspects, the first wafer, e.g., the FZ wafer, and the second wafer, e.g., the CMOS wafer, may be bonded, for example, by bonding a first-wafer bonding layer, e.g., an FZ-wafer bonding layer, and a second-wafer bonding layer, e.g., a CMOS-wafer bonding layer, into a bonded-wafer bonding layer.

In some demonstrative aspects, the bonded-wafer bonding layer may include bonding layer 125.

In some demonstrative aspects, the first-wafer bonding layer, e.g., the FZ-wafer bonding layer, and the second-wafer bonding layer, e.g., the CMOS-wafer bonding layer, may include fusion bonding layers, for example, including a dielectric layer, e.g., a Silicon Dioxide (SiO2) layer.

For example, the first-wafer bonding layer, e.g., the FZ-wafer bonding layer, may include a first fusion bonding layer; and/or the second-wafer bonding layer, e.g., the CMOS-wafer bonding layer, may include a second fusion bonding layer.

In some demonstrative aspects, the first wafer, e.g., the FZ wafer, and the second wafer, e.g., the CMOS wafer, may be bonded, for example, by fusion bonding, for example, to bond the first fusion bonding layer of the FZ wafer with the second fusion bonding layer of the CMOS wafer.

In some demonstrative aspects, the first-wafer bonding layer, e.g., the FZ-wafer bonding layer, and the second-wafer bonding layer, e.g., the CMOS-wafer bonding layer, may include hybrid bonding layers, for example, including dielectric regions and metal vias, e.g., copper vias.

For example, the first-wafer bonding layer, e.g., the FZ-wafer bonding layer, may include a first hybrid bonding layer; and/or the second-wafer bonding layer, e.g., the CMOS-wafer bonding layer, may include a second hybrid bonding layer.

In some demonstrative aspects, the first wafer, e.g., the FZ wafer, and the second wafer, e.g., the CMOS wafer, may be bonded, for example, by hybrid bonding, for example, to bond metal vias and dielectric regions in the first hybrid bonding layer of the FZ wafer with respective metal vias and dielectric regions in the second hybrid bonding layer of the CMOS wafer.

In some demonstrative aspects, the first wafer, e.g., the FZ wafer, and the second wafer, e.g., the CMOS wafer, may be bonded, for example, to connect the metal vias of the FZ wafer with respective metal vias of the CMOS wafer.

In some demonstrative aspects, a thickness of the bonded wafer may be reduced, e.g., after the bonding of the first wafer and the second wafer, for example, by grinding and etching an external surface of an SOI CMOS wafer, e.g., until an etch stop at the BOX layer of the SOI CMOS wafer.

In some demonstrative aspects, the thickness of the bonded wafer may be reduced, for example, such that a thickness of the CMOS wafer may be between 5-10 um, e.g., while a thickness of the bonded wafer may be greater than 300 um, for example, greater than 500 um. for example, greater than 600 um. e.g., about 650 um.

In some demonstrative aspects, the ratio between the thickness of the CMOS wafer and the thickens of the bonded wafer may provide a technical solution to support stacking a plurality of bonded wafers to form a plurality of 3D radiation detectors, for example, while avoiding “dead sensing zones” in a 3D radiation detector.

In some demonstrative aspects, a plurality of TSVs may be formed in the bonded wafer, e.g., after thinning of the bonded wafer.

In some demonstrative aspects, the plurality of TSVs may be formed in the bonded wafer, for example, to connect electronic circuitry in the CMOS wafer and detection sensors in the FZ wafer to a communication interface.

In one example, the communication interface may include communication interface 306 (FIG. 3).

In one example, the communication interface may include the plurality of connection pads 205 (FIG. 2).

In some demonstrative aspects, a plurality of FZ TSVs may be formed in a diffusion-bonded wafer, for example, to connect electronic circuitry in the CMOS wafer and detection sensors in the FZ wafer to the communication interface, for example, in case the bonded wafer is formed by the fusion bonding, e.g., when there may be no connection between the first wafer and the second wafer. For example, plurality of FZ TSVs may include shallow TSVs.

For example, the FZ TSVs may be connected to Aluminum (Al) pads of detection diodes in the FZ wafer.

In some demonstrative aspects, CMOS TSVs may be formed in the CMOS wafer, for example, to connect the electronic circuitry in the CMOS wafer to the external interface, for example, in case the bonded wafer is formed by the hybrid bonding, e.g., when metal vias 128 may provide connections between the first wafer and the second wafer.

For example, the CMOS TSVs may be connected to metal electrodes (M1), e.g., copper electrodes, of transistors in the CMOS wafer.

In some demonstrative aspects, a plurality of bonded wafers may be stacked to form a stack of bonded wafers, e.g., after forming the TSVs in the bonded wafers.

In some demonstrative aspects, the TSVs in the bonded wafers may be implemented as “dummy” TSVs, which may be used as alignment marks, for example, for precision bonding of the bonded wafers.

For example, the stack of bonded wafers may include a plurality of 3D MAPS radiation detectors.

In some demonstrative aspects, the stack of bonded wafers may be singulated, for example, by etching and/or any other cutting method.

In some demonstrative aspects, the stack of bonded wafers may be singulated, for example, into a plurality of chips, for example, to form a plurality of 3D MAPS radiation detectors.

For example, a chip may include a 3D MAPS radiation detector.

In some demonstrative aspects, the bonded wafer may be singulated, for example, to form a plurality of chips.

For example, a chip may include a bonded die 104.

In some demonstrative aspects, the bonded wafer may be singulated, for example, by etching and/or any other cutting method.

In some demonstrative aspects, the plurality of chips may be stacked, for example, to form a 3D MAPS radiation detector.

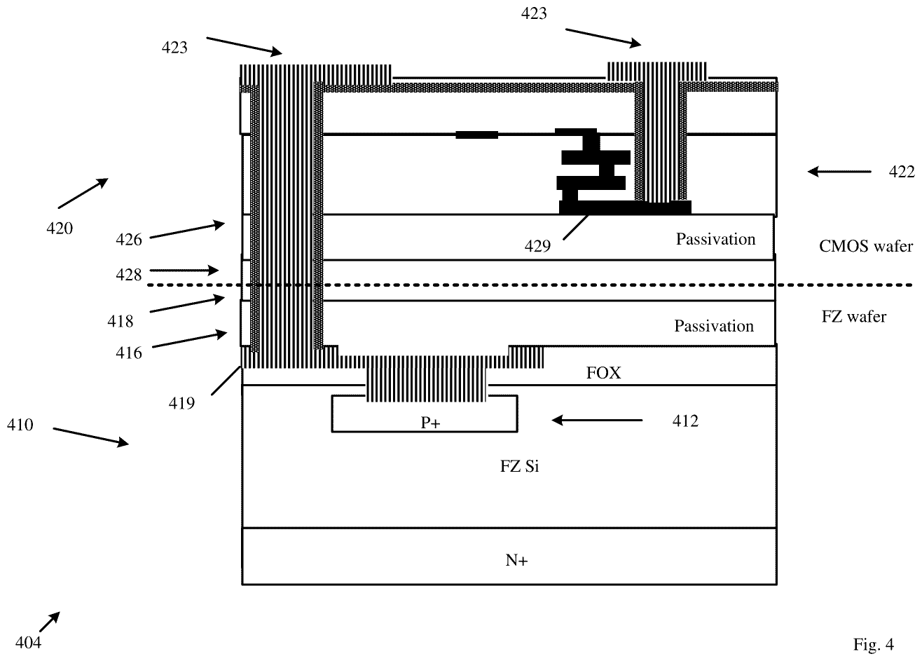

Reference is made to FIG. 4, which schematically illustrates a diffusion-bonded die 404, in accordance with some demonstrative embodiments.

In one example, bonded die 104 (FIG. 1) may include one or more elements of diffusion-bonded die 404.

In some demonstrative aspects, the diffusion-bonded die 404 may be formed according to a two-wafer-diffusion-bonding process, e.g., as described below.

In some demonstrative aspects, diffusion-bonded die 404 may be formed according to a first manufacturing process on a first wafer 410, e.g., including a first semiconductor material, and a second manufacturing process on a second wafer 420, e.g., including a second semiconductor material, e.g., different from the first semiconductor material.

In some demonstrative aspects, as shown in FIG. 4, the first wafer 410 may include a FZ wafer 410.

In some demonstrative aspects, as shown in FIG. 4, the second wafer 420 may include a CMOS wafer 420, e.g., an SOI CMOS wafer 420.

In some demonstrative aspects, as shown in FIG. 4, diffusion-bonded die 404 may include a detection sensor 412 in the first wafer 410.

In some demonstrative aspects, as shown in FIG. 4, detection sensor 412 may include one or more P+ regions and one or more N+ regions (not shown in FIG. 4) in FZ wafer 410, and an N+ doping layer on a back side of the FZ wafer 410, for example, in case the FZ wafer has N+ conductivity.

In other aspects, detection sensor 412 may include one or more N+ regions and one or more P+ regions in FZ wafer 410, and a P+ doping layer on a back side of the FZ wafer 410, for example, in case the FZ wafer has P+ conductivity.

In some demonstrative aspects, as shown in FIG. 4, detection sensor 412 may include a passivation layer 416.

In some demonstrative aspects, as shown in FIG. 4, the detection sensor 412 may include a bonding layer 418.

In some demonstrative aspects, as shown in FIG. 4, the bonding layer 418 may include a dielectric layer, e.g., a Tetraethoxysilane based (TEOS) layer, or any other layer.

In some demonstrative aspects, as shown in FIG. 4, diffusion-bonded die 404 may include electronic circuitry 422 in the second wafer 420, e.g., the CMOS wafer.

In some demonstrative aspects, as shown in FIG. 4, the electronic circuitry 422 may include one or more MOS transistors, e.g., PMOS and/or NMOS transistors in the CMOS wafer 420.

In some demonstrative aspects, as shown in FIG. 4, the electronic circuitry 422 may include a passivation layer 426 on the CMOS wafer.

In some demonstrative aspects, as shown in FIG. 4, the electronic circuitry 422 may include a bonding layer 428 on the CMOS wafer.

In some demonstrative aspects, as shown in FIG. 4, the bonding layer 428 may include a dielectric layer, e.g., a TEOS layer or any other layer.

In some demonstrative aspects, as shown in FIG. 4, the FZ wafer 410 and the CMOS wafer 420 may be bonded, for example, by fusion bonding.

In some demonstrative aspects, the FZ wafer 410 and the CMOS wafer 420 may be bonded, for example, by bonding two dielectric layers, e.g., by bonding the bonding layer 428 with the bonding layer 418.

In one example, the first wafer 410, e.g., the FZ wafer, and the second wafer 420, e.g., the CMOS wafer, may be bonded, for example, utilizing a low temperature process, e.g., with temperatures below 350 degrees Celsius, for example, to maintain the high resistivity of the FZ wafer.

In other aspects, the first wafer 410, e.g., the FZ wafer, and the second wafer 420, e.g., the CMOS wafer, may be bonded, for example, according to any other process utilizing any other temperatures.

In some demonstrative aspects, as shown in FIG. 4, the CMOS wafer 420 may have a reduced thickness, which may be achieved, for example, by grinding and/or etching an external surface of the SOI CMOS wafer 420, e.g., until an etch stop at a BOX layer of the SOI CMOS wafer 420.

In some demonstrative aspects, the CMOS wafer 420 may have a reduced thickness, for example, a thickness between 5-10 um, e.g., while the FZ wafer 410 may have a thickness greater than 300 um, e.g., a thickness of about 650 um.

In some demonstrative aspects, as shown in FIG. 4, the diffusion-bonded die 404 may include FZ TSVs 423, for example, to connect electronic circuitry 422 in the CMOS wafer 420 to an external interface, and/or to connect the detection sensor 412 in the FZ wafer 420 to an external interface. For example, the FZ TSVs 423 may be implemented in case there may be no connections between the first wafer 410 and the second wafer 420.

For example, the FZ TSVs 423 may be connected to Al pads 419 of detection diodes in the FZ wafer 410.

For example, the FZ TSVs 423 may be connected to metal electrodes 429 of electronic circuitry 422 in the CMOS wafer 420.

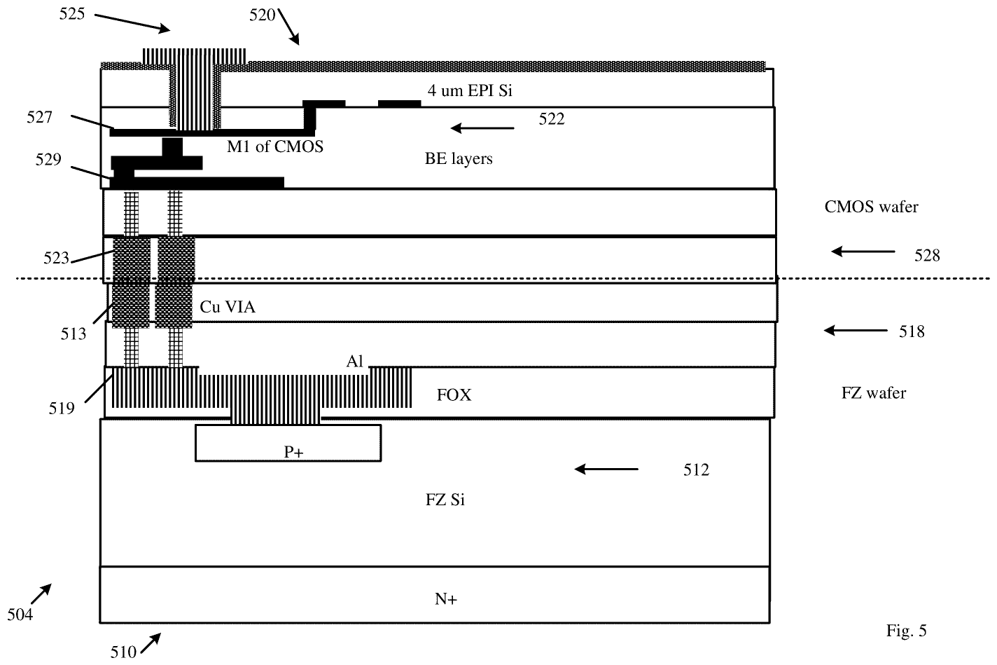

Reference is made to FIG. 5, which schematically illustrates a hybrid-bonded die 504, in accordance with some demonstrative embodiments.

In one example, bonded die 104 (FIG. 1) may include one or more elements of hybrid-bonded die 504.

In some demonstrative aspects, hybrid-bonded die 504 may be formed according to a two-wafer-hybrid-bonding process, e.g., as described below.

In some demonstrative aspects, hybrid-bonded die 504 may be formed according to a first manufacturing process on a first wafer 510, e.g., including a first semiconductor material, and a second manufacturing process on a second wafer 520, e.g., including a second semiconductor material different from the first semiconductor material.

In some demonstrative aspects, as shown in FIG. 5, the first wafer 510 may include an FZ wafer 510.

In some demonstrative aspects, as shown in FIG. 5, the second wafer 520 may include a CMOS wafer 520.

In some demonstrative aspects, as shown in FIG. 5, hybrid-bonded die 504 may include a detection sensor 512 in the first wafer 510.

In some demonstrative aspects, as shown in FIG. 5, the detection sensor 512 may include one or more P+ regions and one or more N+ regions (not shown in FIG. 5) in FZ wafer 510; and an N+ doping layer on a back side of the FZ wafer 510, for example, in case the FZ wafer has N+ conductivity.

In other aspects, the detection sensor 512 may include one or more N+ regions and one or more P+ regions in FZ wafer 510; and a P+ doping layer on a back side of the FZ wafer 510, for example, in case the FZ wafer has P+ conductivity.

In some demonstrative aspects, as shown in FIG. 5, the detection sensor 512 may include a bonding layer 518.

In some demonstrative aspects, as shown in FIG. 5, the bonding layer 518 may include metal vias 513, e.g., copper vias, in a dielectric material of bonding layer 518.

In some demonstrative aspects, as shown in FIG. 5, metal vias 513 may be connected between Al pads 519 of detection diodes in the FZ wafer 510 and a bonded surface of FZ wafer 510.

In some demonstrative aspects, as shown in FIG. 5, hybrid-bonded die 504 may include electronic circuitry 522 in the second wafer 520, e.g., the CMOS wafer.

In some demonstrative aspects, as shown in FIG. 5, the electronic circuitry 522 may include one or more MOS transistors, e.g., PMOS and/or NMOS transistors in the CMOS wafer 520.

In some demonstrative aspects, as shown in FIG. 5, the electronic circuitry 522 may include a bonding layer 528 on the CMOS wafer.

In some demonstrative aspects, as shown in FIG. 5, the bonding layer 528 may include metal vias 523, e.g., copper vias, in a dielectric material of bonding layer 528.

In some demonstrative aspects, as shown in FIG. 5, metal vias 523 may be connected between metal electrodes 529 of electronic circuitry 522 and a bonding surface of CMOS wafer 520.

In some demonstrative aspects, as shown in FIG. 5, the FZ wafer 510 and the CMOS wafer 520 may be bonded, for example, by hybrid bonding.

In some demonstrative aspects, the FZ wafer 510 and the CMOS wafer 520 may be bonded, for example, by bonding the bonding layer 528 and the bonding layer 518, such that metal vias 513 and dielectric regions of the FZ wafer 510 may be aligned with, and/or connected to, and respective metal vias 523 and dielectric regions of the CMOS wafer 520.

In some demonstrative aspects, as shown in FIG. 5, metal vias 523 may be connected to metal vias 513, for example, to support connection of electronic circuitry 522 to detection sensor 512, for example, via a connection between metal electrodes 529 of electronic circuitry 522 and aluminum pads 519 of detection sensor 512.

In one example, the first wafer 510, e.g., the FZ wafer, and the second wafer 520, e.g., the CMOS wafer, may be bonded, for example, utilizing a low temperature process, e.g., with temperatures below 350 degrees Celsius, for example, to maintain the high resistivity of the FZ wafer 510.

In other aspects, the first wafer 510, e.g., the FZ wafer, and the second wafer 520, e.g., the CMOS wafer, may be bonded, for example, according to any other process utilizing any other temperatures.

In some demonstrative aspects, as shown in FIG. 5, the CMOS wafer 520 may have a reduced thickness, which may be achieved, for example, by grinding and/or etching an external surface of the CMOS wafer 520, e.g., until an etch stop at a BOX layer of the CMOS wafer 520.

In some demonstrative aspects, the CMOS wafer 520 may have a reduced thickness, for example, a thickness between 5-10 um, e.g., while the FZ wafer 510 may have a thickness greater than 300 um, e.g., a thickness of about 650 um.

In some demonstrative aspects, as shown in FIG. 5, hybrid-bonded die 504 may include CMOS TSVs 525, for example, to connect the electronic circuitry 522 in the CMOS wafer 520 to an external interface. For example, the CMOS TSVs 525 may be implemented in case connections between the first wafer 510 and the second wafer 520 may be based on the metal vias 513 and the metal vias 523.

For example, the CMOS TSVs 525 may be connected to metal electrodes 527, e.g., copper electrodes, of electronic circuitry 522.

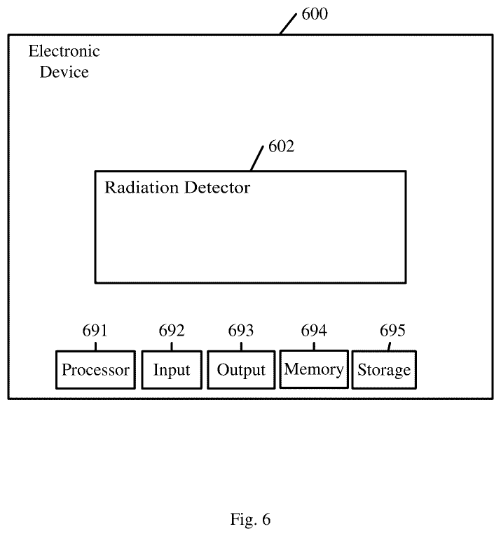

Reference is made to FIG. 6, which schematically illustrates a block diagram of an electronic device 600, in accordance with some demonstrative aspects.

In some demonstrative aspects, electronic device 600 may be configured to detect and/or sense ionizing radiation.

In some demonstrative aspects, electronic device 600 may be configured to determine, process, handle, and/or analyze radiation information with respect to detected ionizing radiation of the ionizing radiation.

In some demonstrative aspects, electronic device 600 may be configured to store, save, record, maintain, load, and/or retrieve the radiation information.

In some demonstrative aspects, electronic device 600 may be configured to provide, output, and/or display information based on the radiation information.

In some demonstrative aspects, electronic device 600 may include a medical device. For example, electronic device 600 may include a CT scan device, which may be configured to provide CT information based on detected Gamma rays (X-rays).

In some demonstrative aspects, electronic device 600 may include a nuclear physics device. For example, electronic device 600 may include a particle detection device of a particle accelerator, which may be configured to provide particle information based on detected high-energy particles.

In some demonstrative aspects, electronic device 600 may include an aerospace device, a security device, or any other type of device.

In some demonstrative aspects, electronic device 600 may include a radiation detector 602, which may be configured to detect the ionizing radiation. For example, radiation detector 602 may include one or more elements of radiation detector 102 (FIG. 1), and/or may perform one or more operations of radiation detector 102 (FIG. 1).

In some demonstrative aspects, radiation detector 602 may be configured to convert the ionizing radiation into an electronic signal, which may be utilized for further processing by the electronic device 600.

In some demonstrative aspects, electronic device 600 may also include, for example, a processor 691, an input unit 692, an output unit 693, a memory unit 694, and/or a storage unit 695. Electronic device 600 may optionally include other suitable hardware components and/or software components. In some demonstrative aspects, some or all of the components of electronic device 600 may be enclosed in a common housing or packaging, and may be interconnected or operably associated using one or more wired or wireless links. In other aspects, components of electronic device 600 may be distributed among multiple or separate devices.

In some demonstrative aspects, processor 691 may include, for example, a Central Processing Unit (CPU), a Digital Signal Processor (DSP), one or more processor cores, a single-core processor, a dual-core processor, a multiple-core processor, a microprocessor, a host processor, a controller, a plurality of processors or controllers, a chip, a microchip, one or more circuits, circuitry, a logic unit, an Integrated Circuit (IC), an Application-Specific IC (ASIC), or any other suitable multi-purpose or specific processor or controller. For example, processor 691 executes instructions, for example, of an Operating System (OS) of electronic device 600 and/or of one or more suitable applications.

In some demonstrative aspects, memory unit 694 may include, for example, a Random Access Memory (RAM), a Read Only Memory (ROM), a Dynamic RAM (DRAM), a Synchronous DRAM (SD-RAM), a flash memory, a volatile memory, a non-volatile memory, a cache memory, a buffer, a short term memory unit, a long term memory unit, or other suitable memory units. Storage unit 695 may include, for example, a hard disk drive, a Solid State Drive (SSD), or other suitable removable or non-removable storage units. For example, memory unit 694 and/or storage unit 695, for example, may store data processed by electronic device 600.

In some demonstrative aspects, input unit 692 may include, for example, a keyboard, a keypad, a mouse, a touch-screen, a touch-pad, a track-ball, a stylus, a microphone, or other suitable pointing device or input device. Output unit 693 includes, for example, a monitor, a screen, a touch-screen, a flat panel display, a Light Emitting Diode (LED) display unit, an Organic LED (OLED) display unit, a Liquid Crystal Display (LCD) display unit, a plasma display unit, one or more audio speakers or earphones, or other suitable output devices.

In some demonstrative aspects, processor 691 may be configured to generate radiation information, for example, based on electronic signals from the radiation detector 602.

For example, processor 691 may be configured to store the radiation information in memory unit 694.

For example, processor 691 may be configured to control output unit 693 to provide output information based on the radiation information.

### Examples

The following examples pertain to further aspects.

Example 1 includes an apparatus comprising a radiation detector configured to detect ionizing radiation, the radiation detector comprising a bonded die comprising a plurality of active pixel sensors configured to sense the ionizing radiation, the bonded die comprising a detection die comprising a plurality of detection diodes, wherein an active pixel sensor of the plurality of active pixel sensors comprises a detection diode of the plurality of detection diodes to generate an electric detection signal based on detected ionized radiation detected by the detection diode; and an electronic-circuitry die bonded to the detection die, wherein a thickness of the electronic-circuitry die is less than 4 percent of a thickness of the detection die, the electronic-circuitry die comprising a plurality of transistors, wherein the active pixel sensor comprises one or more transistors of the plurality of transistors to amplify the electronic detection signal.

Example 2 includes the subject matter of Example 1, and optionally, wherein the detection die comprises Float-Zone (FZ) silicon.

Example 3 includes the subject matter of Example 1 or 2, and optionally, wherein the detection die comprises high-resistance Float-Zone (FZ) silicon.

Example 4 includes the subject matter of any one of Examples 1-3, and optionally, wherein the detection die comprises fully-depleted silicon.

Example 5 includes the subject matter of Example 1, and optionally, wherein the detection die comprises a Czochralski silicon die.

Example 6 includes the subject matter of Example 5, and optionally, wherein the detection die comprises a high-resistance Czochralski silicon die.

Example 7 includes the subject matter of any one of Examples 1-6, and optionally, wherein the electronic-circuitry die comprises a Complementary Metal-Oxide-Semiconductor (MOS) (CMOS) die comprising a plurality of MOS transistors.

Example 8 includes the subject matter of Example 7, and optionally, wherein the plurality of MOS transistors comprises a plurality of N-type MOS (NMOS) transistors.

Example 9 includes the subject matter of Example 7, and optionally, wherein the plurality of MOS transistors comprises a plurality of P-type MOS (PMOS) transistors.

Example 10 includes the subject matter of any one of Examples 1-9 comprising a bonding layer to bond the electronic-circuitry die and the detection die.

Example 11 includes the subject matter of Example 10, and optionally, wherein the bonding layer comprises a fusion bonding layer to fuse a dielectric layer of the electronic-circuitry die with a dielectric layer of the detection die.

Example 12 includes the subject matter of Example 10, and optionally, wherein the bonding layer comprises a hybrid bonding layer to bond dielectric regions and metal vias of the electronic-circuitry die with corresponding dielectric regions and metal vias of the detection die.

Example 13 includes the subject matter of any one of Examples 10-12, and optionally, wherein the bonding layer comprises a plurality of vias to connect the plurality of detection diodes to the plurality of transistors.

Example 14 includes the subject matter of any one of Examples 1-13, and optionally, wherein the radiation detector comprises a plurality of stacked bonded dies to detect the ionizing radiation.

Example 15 includes the subject matter of Example 14, and optionally, wherein the plurality of stacked bonded dies comprises a plurality of connection pads, wherein a connection pad of a stacked bonded die comprising the bonded die is configured to provide a plurality of amplified detection signals from the plurality of active pixels.

Example 16 includes the subject matter of Example 15, and optionally, wherein the plurality of connection pads are arranged in a cascaded arrangement.

Example 17 includes the subject matter of Example 15 or 16, and optionally, wherein the plurality of stacked bonded dies comprises a plurality of spaces between the plurality of connection pads.

Example 18 includes the subject matter of any one of Examples 15-17, and optionally, wherein the plurality of stacked bonded dies comprises a connection interface on an external stacked bonded die, and a plurality of Through-Silicon Vias (TSVs) to connect between the connection interface and transistors of the plurality of stacked bonded dies.

Example 19 includes the subject matter of Example 18, and optionally, wherein the plurality of TSVs comprises a plurality of alignment TSVs to align stacking of the plurality of stacked bonded dies.

Example 20 includes the subject matter of any one of Examples 1-19, and optionally, wherein the detection die comprises an N-type-conductivity detection die comprising one or more heavily doped P-type (P+) regions connected to one or more metal pads, and a heavily doped N-type (N+) layer on an external side of the detection die.

Example 21 includes the subject matter of any one of Examples 1-20, and optionally, wherein the detection die comprises a P-type-conductivity detection die comprising one or more heavily doped N-type (N+) regions connected to one or more metal pads, and a heavily doped P-type (P+) layer on an external side of the detection die.

Example 22 includes the subject matter of any one of Examples 1-21, and optionally, wherein the thickness of the electronic-circuitry die is no more than 3.5 percent of the thickness of the detection die.

Example 23 includes the subject matter of any one of Examples 1-22, and optionally, wherein the thickness of the electronic-circuitry die is no more than 3 percent of the thickness of the detection die.

Example 24 includes the subject matter of any one of Examples 1-23, and optionally, wherein the thickness of the electronic-circuitry die is no more than 2 percent of the thickness of the detection die.

Example 25 includes the subject matter of any one of Examples 1-24, and optionally, wherein the thickness of the detection die is at least 600 micrometer (um).

Example 26 includes the subject matter of any one of Examples 1-25, and optionally, wherein the thickness of the detection die is at least 640 micrometer (um).

Example 27 includes the subject matter of any one of Examples 1-26, and optionally, wherein the thickness of the electronic-circuitry die is no more than 15 micrometer (um).

Example 28 includes the subject matter of any one of Examples 1-27, and optionally, wherein the thickness of the electronic-circuitry die is no more than 10 micrometer (um).

Example 29 includes the subject matter of any one of Examples 1-28, and optionally, wherein the thickness of the electronic-circuitry die is no more than 5 micrometer (um).

Example 30 includes the subject matter of any one of Examples 1-29, and optionally, wherein the detection diode comprises a P-type-Intrinsic-region-N-type (PIN) diode.

Example 31 includes the subject matter of any one of Examples 1-30, and optionally, wherein the radiation detector comprises a Monolithic Active Pixel Sensor (MAPS).

Example 32 includes the subject matter of any one of Examples 1-31, and optionally, wherein the radiation detector comprises a three dimensional (3D) Monolithic Active Pixel Sensor (MAPS) comprising a plurality of stacked bonded dies to detect the ionizing radiation.

Example 33 includes an electronic device comprising a radiation detector configured to detect ionizing radiation, the radiation detector comprising a bonded die comprising a plurality of active pixel sensors configured to sense the ionizing radiation, the bonded die comprising a detection die comprising a plurality of detection diodes, wherein an active pixel sensor of the plurality of active pixel sensors comprises a detection diode of the plurality of detection diodes to generate an electric detection signal based on detected ionized radiation detected by the detection diode; and an electronic-circuitry die bonded to the detection die, wherein a thickness of the electronic-circuitry die is less than 4 percent of a thickness of the detection die, the electronic-circuitry die comprising a plurality of transistors, wherein the active pixel sensor comprises one or more transistors of the plurality of transistors to amplify the electronic detection signal; a processor to generate radiation information based on electronic detection signals from the radiation detector; and a memory to store information processed by the processor.

Example 34 includes the electronic device of Example 33, and optionally, including the subject matter of any of Examples 1-32.

Example 35 includes an apparatus comprising means for performing any of the described operations of any of Examples 1-34.

Example 36 includes a method including any of the described operations of any of Examples 1-34.

Functions, operations, components and/or features described herein with reference to one or more aspects, may be combined with, or may be utilized in combination with, one or more other functions, operations, components and/or features described herein with reference to one or more other aspects, or vice versa.

While certain features have been illustrated and described herein, many modifications, substitutions, changes, and equivalents may occur to those skilled in the art. It is, therefore, to be understood that the appended claims are intended to cover all such modifications and changes as fall within the true spirit of the invention.

What is claimed is:

1. An apparatus comprising:
a radiation detector configured to detect ionizing radiation, the radiation detector comprising a bonded die comprising a plurality of active pixel sensors configured to sense the ionizing radiation, the bonded die comprising:
a detection die comprising a plurality of detection diodes, wherein an active pixel sensor of the plurality of active pixel sensors comprises a detection diode of the plurality of detection diodes to generate an electric detection signal based on detected ionized radiation detected by the detection diode; and
an electronic-circuitry die bonded to the detection die, wherein a thickness of the electronic-circuitry die is less than 4 percent of a thickness of the detection die, the electronic-circuitry die comprising a plurality of transistors, wherein the active pixel sensor comprises one or more transistors of the plurality of transistors to amplify the electronic detection signal.

2. The apparatus of claim 1, wherein the detection die comprises Float-Zone (FZ) silicon.

3. The apparatus of claim 1, wherein the detection die comprises fully-depleted silicon.

4. The apparatus of claim 1, wherein the detection die comprises a Czochralski silicon die.

5. The apparatus of claim 4, wherein the detection die comprises a high-resistance Czochralski silicon die.

6. The apparatus of claim 1, wherein the electronic-circuitry die comprises a Complementary Metal-Oxide-Semiconductor (MOS) (CMOS) die comprising a plurality of MOS transistors.

7. The apparatus of claim 1 comprising a bonding layer to bond the electronic-circuitry die and the detection die.

8. The apparatus of claim 7, wherein the bonding layer comprises a fusion bonding layer to fuse a dielectric layer of the electronic-circuitry die with a dielectric layer of the detection die.

9. The apparatus of claim 7, wherein the bonding layer comprises a hybrid bonding layer to bond dielectric regions and metal vias of the electronic-circuitry die with corresponding dielectric regions and metal vias of the detection die.

10. The apparatus of claim 7, wherein the bonding layer comprises a plurality of vias to connect the plurality of detection diodes to the plurality of transistors.

11. The apparatus of claim 1, wherein the radiation detector comprises a plurality of stacked bonded dies to detect the ionizing radiation.

12. The apparatus of claim 11, wherein the plurality of stacked bonded dies comprises a plurality of connection pads, wherein a connection pad of a stacked bonded die comprising the bonded die is configured to provide a plurality of amplified detection signals from the plurality of active pixels.

13. The apparatus of claim 12, wherein the plurality of connection pads are arranged in a cascaded arrangement.

14. The apparatus of claim 12, wherein the plurality of stacked bonded dies comprises a plurality of spaces between the plurality of connection pads.

15. The apparatus of claim 12, wherein the plurality of stacked bonded dies comprises a connection interface on an external stacked bonded die, and a plurality of Through-Silicon Vias (TSVs) to connect between the connection interface and transistors of the plurality of stacked bonded dies.

16. The apparatus of claim 15, wherein the plurality of TSVs comprises a plurality of alignment TSVs to align stacking of the plurality of stacked bonded dies.

17. The apparatus of claim 1, wherein the thickness of the electronic-circuitry die is no more than 3 percent of the thickness of the detection die.

18. The apparatus of claim 1, wherein the thickness of the detection die is at least 600 micrometer (um).

19. The apparatus of claim 1, wherein the thickness of the electronic-circuitry die is no more than 15 micrometer (um).

20. The apparatus of claim 1, wherein the thickness of the electronic-circuitry die is no more than 5 micrometer (um).

21. The apparatus of claim 1, wherein the detection diode comprises a P-type-Intrinsic-region-N-type (PIN) diode.

22. The apparatus of claim 1, wherein the radiation detector comprises a Monolithic Active Pixel Sensor (MAPS).

23. The apparatus of claim 1, wherein the radiation detector comprises a three dimensional (3D) Monolithic Active Pixel Sensor (MAPS) comprising a plurality of stacked bonded dies to detect the ionizing radiation.

24. An electronic device comprising:
a radiation detector configured to detect ionizing radiation, the radiation detector comprising a bonded die comprising a plurality of active pixel sensors configured to sense the ionizing radiation, the bonded die comprising:
a detection die comprising a plurality of detection diodes, wherein an active pixel sensor of the plurality of active pixel sensors comprises a detection diode of the plurality of detection diodes to generate an electric detection signal based on detected ionized radiation detected by the detection diode; and
an electronic-circuitry die bonded to the detection die, wherein a thickness of the electronic-circuitry die is less than 4 percent of a thickness of the detection die, the electronic-circuitry die comprising a plurality of transistors, wherein the active pixel sensor comprises one or more transistors of the plurality of transistors to amplify the electronic detection signal;
a processor to generate radiation information based on electronic detection signals from the radiation detector; and
a memory to store information processed by the processor.

25. The electronic device of claim 24, wherein the radiation detector comprises a plurality of stacked bonded dies to detect the ionizing radiation.
